(19) United States
(12) Patent Application Publication
(10) Pub. No.: US 2008/0019406 A1
(43) Pub. Date: Jan. 24, 2008

(54) Vertical External Cavity Surface Emitting Laser

(76) Inventors: Richard H. Abram, Edinburgh (GB); Allister I Ferguson, Glasgow (GB); Erling Riis, Blanefield (GB)

Correspondence Address: KED & ASSOCIATES, LLP, P.O. Box 221200, Chantilly, VA, 20153-1200, US

(21) Appl. No.: 10/581,665

(22) PCT Filed: Dec. 3, 2004
(86) PCT No.: PCT/GB04/05142

§ 371 Date: Jul. 2, 2007

(30) Foreign Application Priority Data
Dec. 4, 2003 (GB) 0328007.0

(51) Int. Cl. H01S 5/024

(52) U.S. Cl. 372/36

(57) ABSTRACT

An improved Vertical External Cavity Surface Emitting Laser (VECSEL) (1, 22, 27, 29) is described that exhibits improved frequency stability and tuning characteristics when compared with known devices. This is achieved through the employment of an intra cavity heatspreader (18) comprising single crystal diamond that is located with the gain medium (14) of the VECSEL (1, 22, 27, 29). As single crystal diamond exhibits good thermal conductivity and is non birefringent it acts as a good heatspreader (18) for the gain medium (14) while not interfering with the polarisation selection properties of any intra cavity birefringent filter (9). A further advantage of the heat spreader (18) being non birefringent is that an optimised anti reflection coating can also be applied this component.

The present invention relates to an improved Vertical External Cavity Surface Emitting Laser (VECSEL) and in particular to a VECSEL that exhibits improved wavelength tuning characteristics.

Diode-pumped and electrically pumped VECSELs are an attractive format of semiconductor laser known to those skilled in the art for scientific, instrumentation and non-linear optics applications. The design and fabrication of a VECSEL laser with Circular TEM₀₀ output beams has been described by Kusnetsov et al (IEEE Journal of selected Topics in Quantum Electronics Vol. 5, Page 561-573 (1999) “Design and Characteristics of High-Power (>0.5 W CW) Diode-Pumped Vertical-External-Cavity Surface-Emitting Semiconductor Lasers with Circular TEM₀₀ Beams”).

The optical gain medium within a VECSEL is provided by the recombination of electrical carriers within very thin layers of a semiconductor material. These layers are generally termed quantum-well (QW) layers or active layers exhibiting a typical thickness of around 150 Å or less.

Application of intracavity spectral and temporal control techniques such as picosecond and subpicosecond mode-locking, single-frequency operation and intracavity second-harmonic generation have also been demonstrated see:
Garnache et al. Appl. Phys. Lett. Vol 80 Page 3892-3894 (2002) “Sub 500-fs Soliton-Like Pulse in a Passively Mode-Locked Broadband Surface-Emitting Laser with 100 mW Average Power”;
Holm et al. IEEE Photon. Technol. Lett. Vol 11 Page 1551-1553 (1999) “Actively stabilised Single-Frequency Vertical-Cavity AlGaAs Laser”; and
Schiehlen et al. IEEE Photon. Technol. Lett. Vol 14 Page 777-779 (2002) “Diode-Pumped Semiconductor Disk Laser With Intracavity Frequency Doubling using Lithium Triborate (LBO)”, respectively.

A significant limiting factor in all of the aforementioned systems is that their output power is greatly limited by the thermal response of the gain medium. Typically, without employing thermoelectric cooler (TEC) mounting techniques or cooling strategically deployed heat sinks with chilled water, both of which are well known to those skilled in the art, the output powers at room temperatures are limited to a few 10's of mW. The employment of these cooling methods act to improve the output powers but are generally very inefficient due to the fact that the heat must be removed from the gain medium via the substrate of the structure.

The prior art teaches of several methods for improving the efficiency of VECSEL cooling systems. The first involves growing the gain structure in reverse order, mounting on a heatsink and etching away the substrate. However, the resultant scattering due to poor surface quality remains a significant problematic feature within low gain lasers that usually tolerate only very little losses (˜4%).

Alford et al. described an alternative method for removing heat from the gain region that involves no post-growth alterations to the structure (see J. Opt. Soc. Am. B Vol. 19, Page 663 (2002) “High Power and Good Beam Quality at 980 nm from a Vertical External-Cavity Surface-Emitting Laser”). In particular this document teaches of an InGaAs-based VECSEL that employs, in conjunction with a thermoelectric cooler, a sapphire heatspreader capillary bonded in optical contact with the epi-side (or active surface) of the gain structure. More recently, Hastie et al. have described a VECSEL that employs an intracavity Silicon Carbide (SiC) heatspreader that is optically contacted to the active surface of the gain medium (see IEEE Photon. Technol. Lett. Vol 15 Page 894-896 (2003) “0.5 W Single Transverse-Mode Operation of an 850 nm Diode Pumped Surface-Emitting Semiconductor Laser”). Generally, Silicon Carbide has been shown to exhibit superior heat spreading characteristics than heatspreaders comprising Sapphire.

In order to produce single frequency operation it is known to those skilled in the art to incorporate intracavity polarisation selecting elements such as birefringent filters, orientated at Brewster's angle, and an etalon within the laser cavity. Wavelength scanning can then be achieved via a number of known techniques e.g. the incorporation of stabilisation to a side of a transmission peak of an external reference cavity. Such techniques are currently employed to produce tuneable Ti:Sapphire and Dye lasers that find particular application in the field of high resolution spectroscopy.

It is known that the gain medium of a VECSEL possesses a relatively high gain bandwidth that provides the potential for a VECSEL to be tuned approximately 20 nm either side of the engineered wavelength. However, in practice it has been found that the above laser frequency stabilisation and wavelength scanning techniques do not lend themselves to be readily incorporated within the described VECSELs. This is principally due to the fact that there is significant modulation of the output power of the VECSEL as the laser's operating wavelength is scanned (between 10-30%) due to the heatspreader acting as an additional intracavity etalon. Furthermore, both Sapphire and Silicon Carbide heat spreading elements are found to interfere with the polarisation selection properties of any intracavity birefringent filter thus reducing the frequency stability and tuneability of the cavity.

It is an object of aspects of the present invention to provide a Vertical External Cavity Surface Emitting Laser (VECSEL) that overcomes one or more of the limiting features on frequency stability and frequency tuning associated with the VECSELs described in the prior art.

According to a first aspect of the present invention there is provided a Vertical External Cavity Surface Emitting Laser comprising: a semiconductor wafer structure, containing a gain medium and a Bragg reflecting region; and a heatspreader associated with the wafer structure such that the gain medium is located between the heatspreader and the Bragg reflecting region, wherein the heatspreader comprises a non-birefringent material.

Preferably the heatspreader comprises a first surface upon which is located an anti-reflection coating.

According to a second aspect of the present invention there is provided a Vertical External Cavity Surface Emitting Laser comprising: a semiconductor wafer structure containing a gain medium and a Bragg reflecting region; and a heatspreader associated with the wafer structure such that the gain medium between is located between the heatspreader and the Bragg reflecting region, wherein the heatspreader comprises a first surface upon which is located an anti-reflection coating.

Most preferably the heatspreader comprises a non-birefringent material.

According to a third aspect of the present invention there is provided a Vertical External Cavity Surface Emitting Laser comprising: a semiconductor wafer structure containing a gain medium and a Bragg reflecting region; and a heatspreader associated with the wafer structure such that the gain medium is located between the heatspreader and the Bragg reflecting region, wherein the heatspreader comprises a non-birefringent material and a first surface upon which is located an anti-reflection coating.

Preferably the anti-reflection coating is optimised for efficient operation with a refractive index of the non-birefringent material and a lasing frequency of the laser.

Preferably the first surface of the heatspreader comprise a wedge.

Most preferably the heatspreader comprises a single diamond crystal.

Optionally lasing of the Vertical External Cavity Surface Emitting Laser is achieved by optical excitement of the gain medium. Alternatively, lasing of the Vertical External Cavity Surface Emitting Laser is achieved by electrical excitement of the gain medium.

Preferably the laser further comprises an intracavity polarisation selecting element that provides a first means for selecting the operating frequency of the laser.

Preferably the intracavity polarisation selecting element comprises a birefringent filter orientated at Brewster's angle.

Preferably the laser further comprises an intracavity etalon that provides a second means for selecting the operating frequency of the laser.

Preferably the laser further comprises an external reference cavity that allows for the frequency stabilisation of the laser output to a side of a transmission peak of the external cavity.

Optionally the laser comprises a three mirror folded cavity arrangement.

Preferably the laser further comprises a cavity mirror mounted on a first piezoelectric crystal and an output coupler mounted on a second piezoelectric crystal wherein the combined movement of the cavity mirror and the output coupler provides a first means for frequency tuning the output of the laser.

Alternatively, the laser further comprises a pair of Brewster plates and a cavity mirror mounted on a piezoelectric crystal wherein the combined movement of the Brewster plates and the cavity mirror provide a second means for frequency tuning the output of the laser.

According to a fourth aspect of the present invention there is provided a frequency scanning Vertical External Cavity Surface Emitting Laser suitable for use in high resolution spectroscopy experiments comprising: apparatus for selecting and stabilising the operating frequency of the laser; apparatus for scanning the operating frequency of the laser; a semiconductor wafer structure containing a gain medium and a Bragg reflecting region; and a heatspreader associated with the wafer structure such that the gain medium is located between the heatspreader and the Bragg reflecting region, wherein the heatspreader comprises a non-birefringent material.

Preferably the heatspreader comprises a first surface upon which is located an anti-reflection coating.

Preferably the apparatus for selecting and stabilising the operating frequency of the laser comprises an intracavity polarisation selecting element that provides a first means for selecting the operating frequency of the laser.

Optionally the apparatus for selecting and stabilising the operating frequency of the laser further comprises an intracavity etalon that provides a second means for selecting the operating frequency of the laser.

Optionally the apparatus for selecting and stabilising the operating frequency of the laser further comprises an external reference cavity that allows for the frequency stabilisation of the laser output to a side of a transmission peak of the external cavity.

Preferably the apparatus for scanning the operating frequency of the laser comprises a cavity mirror mounted on a first piezoelectric crystal and an output coupler mounted on a second piezoelectric crystal wherein the combined movement of the cavity mirror and the output coupler provides a first means for frequency tuning the output of the laser.

Alternatively, the apparatus for scanning the operating frequency of the laser comprises a pair of Brewster plates and a cavity mirror mounted on a piezoelectric crystal wherein the combined movement of the Brewster plates and the cavity mirror provides a second means for frequency tuning the output of the laser.

Preferably the anti-reflection coating is optimised for efficient operation with a refractive index of the non-birefringent material and a lasing frequency of the laser.

Preferably the first surface of the heatspreader comprise a wedge.

Most preferably the heatspreader comprises a single diamond crystal.

Aspects and advantages of the present invention will become apparent upon reading the following detailed description and upon reference to the following drawings in which:

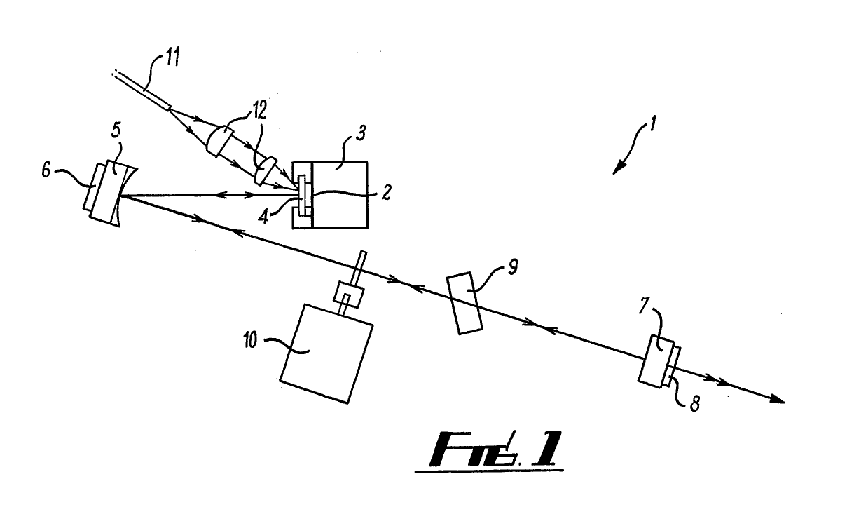

FIG. 1 presents a schematic representation of an improved Vertical External Cavity Surface Emitting Laser (VECSEL) that incorporates intracavity elements for single frequency selection;

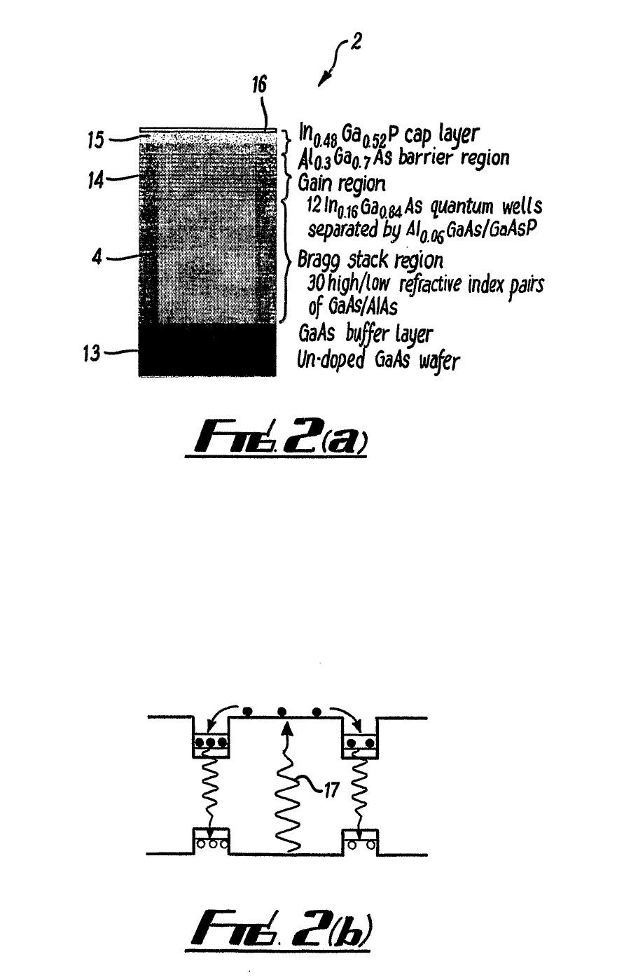

FIG. 2 presents:
(a) a schematic representation; and
(b) a schematic bandgap diagram, of the gain medium of a 980 nm VECSEL of FIG. 1;

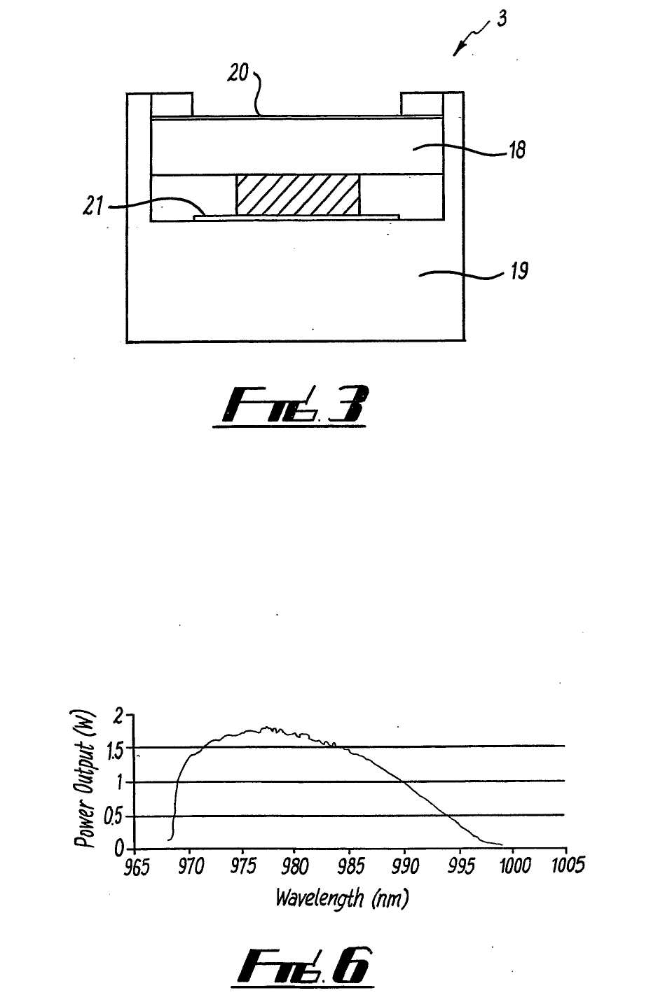

FIG. 3 presents further detail of the cooling apparatus and a heatspreader employed by the VECSEL of FIG. 1;

FIG. 4 presents an output power curve, as a function of pump power, for the VECSEL of FIG. 1 designed to operate around a 980 nm central output wavelength;

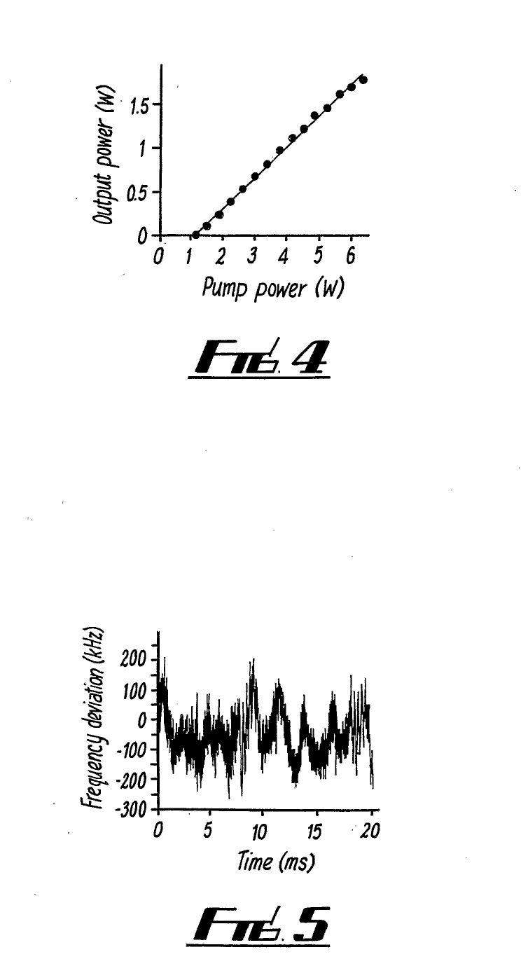

FIG. 5 presents a measured residual frequency noise output for the 980 nm VECSEL of FIG. 1;

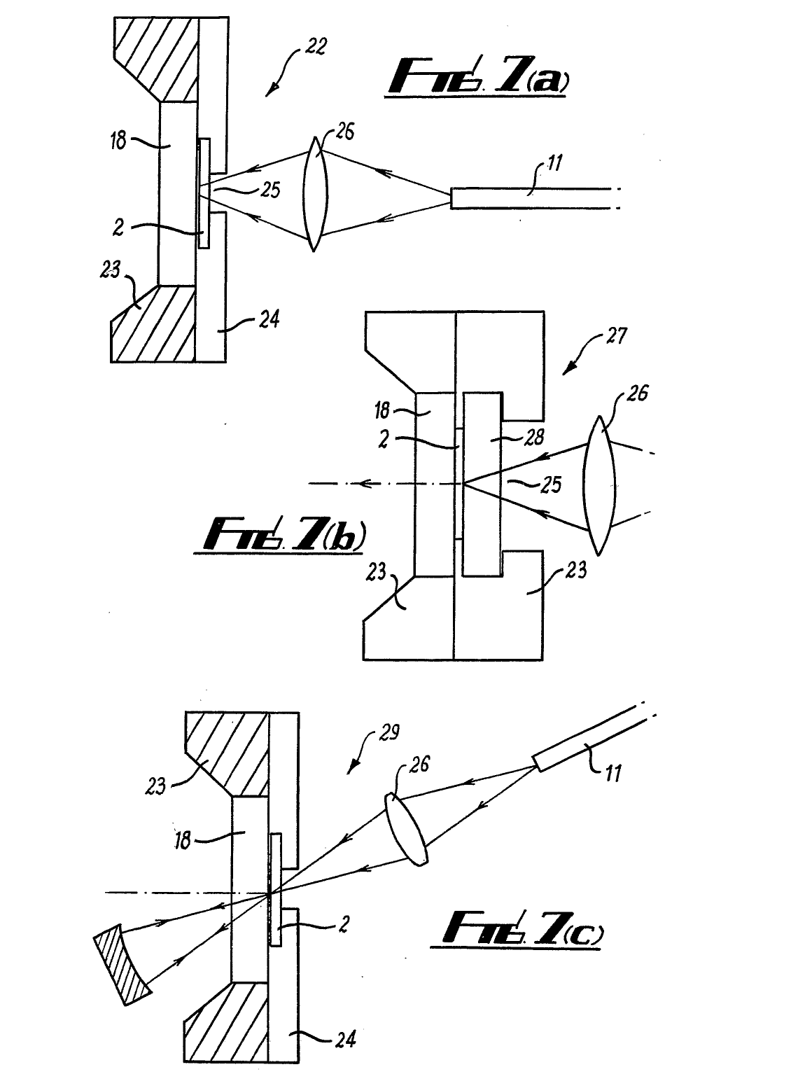

FIG. 6 presents a measured wavelength tuning curve for the 980 nm VECSEL of FIG. 1 when coupled to a transmission peak of an external reference cavity; and

FIG. 7 presents schematic detail of:
(a) an on axis back pumped VECSEL;
(b) an on axis back pumped VECSEL that incorporates a second heatspreader; and
(c) an off-axis back pumped VECSEL;
in accordance with various aspects of the present invention.

Referring to FIG. 1 a schematic representation of a Vertical External Cavity Surface Emitting Laser (VECSEL) 1, in accordance with an aspect of the present invention is provided. The VECSEL 1 can be seen to comprise a semiconductor wafer structure 2 mounted within a cooling apparatus 3 that is located within a three mirror folded cavity arrangement.

A first mirror within the cavity arrangement comprises a Bragg reflector region 4 integrated within the wafer structure 2 (further details of which are outlined below). A second mirror comprises a standard curved cavity mirror 5 mounted on a first piezoelectric crystal 6 so allowing for fine adjustment of the length of the cavity. An output coupler 7, mounted on a second piezoelectric crystal 8 so allowing for coarse adjustment of the length of the cavity, is then employed as the third cavity mirror. Between the curved cavity mirror 5 and the output coupler 7 are located a birefringent filter 9 employed to provide coarse frequency selection within the cavity and a solid etalon 10 employed for fine frequency selection of the operating wavelength. The wafer structure 2 is optically pumped by initially coupling the output of a pump laser source (not shown) into an optical fibre 11. Thereafter, the coupled pump laser output is focussed via two input lens elements 12 onto the wafer structure 2.

A schematic representation of the wafer structure 2 is presented in FIG. 2(a). The wafer structure 2 is grown by a metal-organic chemical vapour deposition (MOCVD) technique on a 2 inch (5.08 cm) 500 mm thick (001) GaAs substrate 13. The wafer structure 2 comprises a single distributed Bragg reflector region 4, a gain medium 14, a carrier confinement potential barrier 15 and an oxidation prevention layer 16.

The Bragg reflector region 4 comprises thirty pairs of AlAs—GaAs quarter-wave layers that exhibit a total reflectivity greater than 99.9% centred at 980 nm while the carrier confinement potential barrier comprises a single wavelength-thick Al_{0.3}Ga_{0.7}As layer. The oxidation prevention layer comprises a thin In_{0.48}Ga_{0.52}P cap.

The gain medium 14 comprises twelve 6 nm thick In_{0.16}GaAs quantum wells equally spaced between half-wave Al_{0.06}Ga_{0.8}AS/GaAsP structures that allow the VECSEL 1 to be optically pumped at 808 nm while generating an output in the range of 970-995 nm. (referred to below as the 980 nm VECSEL)

A schematic representation of the lasing mechanism is presented in the bandgap diagram of FIG. 2 (b). The pump field 17 is absorbed in the barrier regions and carriers thereafter diffuse into the quantum wells so as to produce the required population inversion for lasing to take place.

FIG. 3 presents further detail of the cooling apparatus 3 and heatspreader 18 employed in order to improve the operating characteristics of the VECSEL 1. In particular the cooling apparatus 3 comprises a standard thermoelectric cooler 19 while the heat spreader 18 comprises a single diamond crystal that comprises an external, wedged face 20. A high performance anti-reflection coating is deposited on the surface of the wedged face 20.

The single diamond crystal heatspreader 18 is bonded in optical contact with the wafer structure 2 so that the gain medium 14 is located between the heatspreader 18 and the Bragg reflector region 4. The wafer structure 2 and heatspreader 18 are then clamped on top of a layer of indium foil 21 onto the thermoelectric cooler 19.

Single diamond crystal is suited to be employed as the heatspreader 18 since it exhibits comparable thermal conductivity levels as Sapphire and Silicon Carbide. Thus, the described arrangement allows the heatspreader 18 to immediately spread the heat generated within the gain medium 14 by the pump field 17 to the cooling apparatus 3 after it has propagated only a limited distance into the gain medium 14, so significantly increasing the efficiency of the device. In addition there are further inherent advantages of employing the single diamond crystal as the heatspreader 18 over those described in the prior art. These reside in the fact that the single diamond crystal is non-birefringent. As such the presence of the heatspreader 18 no longer interferes with polarisation selecting properties of the birefringent filter 9 and so there are no additional intracavity losses experienced on the output of the VECSEL 1 as the laser is tuned (see FIG. 6 below).

The lack of birefringence within the heatspreader 18 also allows for an optimised anti-reflection coating to be applied to the surface of the wedged face 20. It is known to those skilled in the art that in order to optimise an anti-reflection coating it is necessary that the refractive index of the medium to which the coating is to be applied is known to a high degree of accuracy. Therefore, if the heatspreader 18 were to exhibit birefringence (as is the case for Sapphire and Silicon Carbide) two effective refractive indices would be present. A direct result of this is that the effective refractive index experienced by a propagating optical field of a fixed polarisation would be critically dependent on the orientation of the heatspreader 18 within the VECSEL 1, restricting alignment to a single orientation only. Practically this would significantly complicate the already difficult cavity alignment process.

However, this is not the case with the single diamond crystal heatspreader 18 thus permitting the incorporation of the anti-reflection coating. The anti-reflection coating acts to significantly reduces the power modulation effects, caused by the presence of the intracavity heatspreader 18, experienced when the 980 nm VECSEL is wavelength tuned (see FIG. 6 below).

FIG. 4 provide some typical operational characteristics of the described VECSEL 1 systems in the absence of the birefringent filter 9 and the solid etalon 10. In particular FIG. 4 presents the 980 nm VESCEL output power as a function of pump power, when the heatsink temperature was maintained at 10° C. The pump power was provided by a commercially available 200 μm fibre coupled laser that generated a 25 W pump field at 808 nm. A 2% output coupler 7 was employed so producing a maximum output power of 1.75 W in a TEM₀₀ mode with 6.2 W of pump power.

On introducing the birefringent filter 9, the solid etalon 10 and a 1% output coupler 7 to the cavity it is possible to stabilise the output frequency of the device to the side of a transmission peak of an external reference cavity (not shown). The operational characteristics of the 980 nm VECSEL are shown in FIG. 5. The VECSEL 1 can be seen to operate at a single frequency exhibiting a residual frequency fluctuation amounting to a linewidth of around 85 kHz r.m.s.

By employing the first 6 and second piezoelectric crystals 8 the curved cavity mirror 5 and the output coupler 7, respectively, can be translated so as to allow for the tuning of the output wavelength of the VECSEL 1. A typical tuning curve for the 980 nm VECSEL is presented in FIG. 6. It should be noted that the modulation in the output power can be seen to have been reduced to less than 5%.

An alternative means for tuning the laser cavity comprises the introduction of a pair of Brewster plates (not shown) into the laser cavity. When the orientation of the Brewster plates are rotated in conjunction with the translational movement of the curved cavity 5 mirror mounted on the piezoelectric crystal 6 the output wavelength of the laser can be scanned, as is known to those skilled in the art.

As will be apparent to those skilled in the art alternative semiconductor wafer structures 2 may be incorporated within the VECSEL 1 in order to provide different operating wavelength ranges. Furthermore, the VECSEL outlined above has been described in relation to a three mirror folded cavity chosen for ease of engineering. However, it will again be readily apparent to those skilled in the art that alternative cavity arrangements may be employed without departing from the scope of the invention. For example the laser cavity may be established between the Bragg reflector 4 and a curved output coupler 7.

In alternative embodiments of the VECSEL the gain medium 14 can be back pumped by arranging the optical pump field 17 to be initially incident on the Bragg reflector region 4 of the semiconductor wafer structure 2, see FIG. 7.

In particular FIG. 7(a) presents a schematic representation of an on axis back pumped VECSEL 22. In this embodiment the wafer structure 2 and the heatspreader 18 are located within a mount 23 formed from a high thermally conductive material e.g. copper. The location of the heatspreader 18 and the wafer structure 2 may be achieved in a number of ways including simply mechanically clamping the heatspreader 18 within the mount 23 with a retaining flange 24, and/or bonding or soldering the heatspreader 18 to the mount 23 and/or by incorporating tapered edges on both the heatspreader 18 and the mount 23 so as to create a compression fit between these components. Suitable materials for producing the retaining flange include copper, as per the present embodiment, or Chemical Vapour Deposition (CVD) diamond.

An aperture 25 is located within the retaining flange 24 so as to allow the pump field 17, provided by the optical fibre 11, to be focused by a lens 26 so as to achieve the required spot size within the gain medium 14. The design of the GaAs substrate 13 and the Bragg reflector region 4 is such that they are substantially transparent to the pump field 17. Propagation of the pump field 17 through the GaAs substrate 13 can be enhanced by introducing an anti-reflection coating optimised for the wavelength of the pump field 17.

In an alternative embodiment of the on axis back pumped VECSEL (not shown) the lens 26 is removed and the optical fibre is abutted directly against the wafer structure 2 via the aperture 25.

FIG. 7(b) presents a schematic representation of an alternative on axis back pumped VECSEL 27. In this arrangement the GaAs substrate 13 has been removed from the semiconductor wafer structure 2 so as to expose the Bragg reflecting region 4. The removal of the GaAs substrate 13 can be simply achieved mechanically or by etching methods, techniques that are already known to those skilled in the art.

Removal of the GaAs substrate 13 has several advantages. In the first instance it reduces the wavelength restrictions on the pump field 17 as it is now only required to propagate through the Bragg reflecting region 4 before being absorbed within the gain medium 14. Secondly, the removal of the GaAs substrate 13 also allows for the incorporation of a second heatspreader 28 that is located in thermal contact with the Bragg reflecting region 4, as shown schematically in FIG. 7(b). This arrangement allows for additional improvement of the operating characteristics of the VECSEL 27. As the second heatspreader 28 is not an intra cavity element the optical criteria placed on this component are significantly reduced when compared with the intra cavity heatspreader 18. Indeed this component can be made from any material that is optically transparent to the pump field and which exhibits good thermal conductivity properties e.g. diamond, sapphire, Silicon Carbide, CVD diamond and glass.

FIG. 7(c) presents a schematic representation of a yet alternative embodiment of the present invention, namely an off-axis back pumped VECSEL 29. In this embodiment an off axis pump field 17 is directed so as to back pump the gain medium, in a similar manner to that described above, through the employment of an off axis arrangement of the optical fibre 11 and lens 26, as shown. An additional intra cavity mirror 30, coated so as to efficiently reflect the pump field 17, is then employed so as to retro reflect any of the pump field 17 not absorbed on the initial pass through the gain medium 14. With this embodiment the efficiency of the absorption of the pump field 17 within the gain medium 14 is increased so improving the overall efficiency of the VECSEL 29.

It will be appreciated by those skilled in the art that the advantages of the additional intra cavity mirror 30 can be harnessed within an on axis embodiment if this mirror is suitably coated so as to reflect light at the wavelength of both the pump field 17 and the VECSEL operating wavelength. With this arrangement the intra cavity mirror 30 thus functions to reflect any unabsorbed pump field 17 back towards the gain medium 14 as previously described, as well as acting as a normal cavity mirror.

The above described VECSELs have all been described in relation to optically pumped systems. However, it will be appreciated by those skilled in the art that the advantages of the heatspreader 18 can readily be incorporated within an electrically pumped VECSEL systems where the electrical contacts are arranged in such a manner so as to allow the heatspreader 18 to be located with gain medium 14.

The VECSELs described above all employ a non-birefringent heatspreader that allows the full tuning potential of the associated gain medium to be exploited. Single diamond crystal is employed as the heatspreader since it provides the required level of thermal conductivity so as to act as an efficient heatspreader. The fact that the heatspreader is non-birefringent means that there is no detrimental interaction between the heatspreader and the polarisation selecting properties of an intracavity birefringent filter employed for coarse frequency selection within the cavity. Furthermore, the fact that heatspreader is non-birefringent allows the application of an optimised anti-refection coating to a surface of the heatspreader so as to significantly reduce the modulation on the output power experienced by prior art systems. This modulation of the output power can be further reduced by arranging that the surface to which the anti-reflection coating is applied is substantially wedged.

The foregoing description of the invention has been presented for purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention herein intended.

1. A Vertical External Cavity Surface Emitting Laser comprising:
a semiconductor wafer structure, containing a gain medium and a Bragg reflecting region; and
a heatspreader associated with the wafer structure such that the gain medium is located between the heatspreader and the Bragg reflecting region, wherein the heatspreader comprises a non-birefringent material.

2. A laser as claimed in claim 1 wherein the heatspreader comprises a first surface upon which is located an anti-reflection coating.

3. A Vertical External Cavity Surface Emitting Laser comprising:
a semiconductor wafer structure containing a gain medium and a Bragg reflecting region; and
a heatspreader associated with the wafer structure such that the gain medium is located between the heatspreader and the Bragg reflecting region, wherein the heatspreader comprises a first surface upon which is located an anti-reflection coating.

4. A laser as claimed in claim 3 wherein the heatspreader comprises a non-birefringent material.

5. A laser as claimed in claim 3 wherein the anti-reflection coating is optimised for efficient operation with a refractive index of the non-birefringent material and a lasing frequency of the laser.

6. A laser as claimed in any of claim 3 wherein the first surface of the heatspreader comprise a wedge.

7. A laser as claimed in claim 1 or 3 wherein the heatspreader comprises a single diamond crystal.

8. A laser as claimed in claim 1 or 3 wherein lasing is achieved by optical excitement of the gain medium.

9. A laser as claimed in claim 1 or 3 wherein lasing is achieved by electrical excitement of the gain medium.

10. A laser as claimed in claim 1 or 3 wherein the laser further comprises an intracavity polarisation selecting element that provides a first means for selecting the operating frequency of the laser.

11. A laser as claimed in claim 10 wherein the intracavity polarisation selecting element comprises a birefringent filter orientated at Brewster's angle.

12. A laser as claimed in claim 1 or 3 wherein the laser further comprises an intracavity etalon that provides a second means for selecting the operating frequency of the laser.

13. A laser as claimed in claim 1 or 3 wherein the laser further comprises an external reference cavity that allows for the frequency stabilisation of the laser output to a side of a transmission peak of the external cavity.

14. A laser as claimed in claim 1 or 3 wherein the laser comprises a three mirror folded cavity arrangement.

15. A laser as claimed in claim 14 wherein the laser further comprises a cavity mirror mounted on a first piezoelectric crystal and an output coupler mounted on a second piezoelectric crystal wherein the combined movement of the cavity mirror and the output coupler provides a first means for frequency tuning the output of the laser.

16. A laser as claimed in claim 14 wherein the laser further comprises a pair of Brewster plates and a cavity mirror mounted on a piezoelectric crystal wherein the combined movement of the Brewster plates and the cavity mirror provide a second means for frequency tuning the output of the laser.

17. A frequency scanning Vertical External Cavity Surface Emitting Laser suitable for use in high resolution spectroscopy experiments comprising:
apparatus for selecting and stabilising the operating frequency of the laser;
apparatus for scanning the operating frequency of the laser;
a semiconductor wafer structure containing a gain medium and a Bragg reflecting region; and
a heatspreader associated with the wafer structure such that the gain medium is located between the heatspreader and the Bragg reflecting region, wherein the heatspreader comprises a material.

18. A laser as claimed in claim 17 wherein the heatspreader comprises a first surface upon which is located an anti-reflection coating.

19. A laser as claimed in claim 17 wherein the apparatus for selecting and stabilising the operating frequency of the laser comprises an intracavity polarisation selecting element that provides a first means for selecting the operating frequency of the laser

20. A laser as claimed in claim 19 wherein the apparatus for selecting and stabilising the operating frequency of the laser further comprises an intracavity etalon that provides a second means for selecting the operating frequency of the laser.

21. A laser as claimed in claim 20 wherein the apparatus for selecting and stabilising the operating frequency of the laser further comprises an external reference cavity that allows for the frequency stabilisation of the laser output to a side of a transmission peak of the external cavity.

22. A laser as claimed in claim 17 wherein the apparatus for scanning the operating frequency of the laser comprises a cavity mirror mounted on a first piezoelectric crystal and an output coupler mounted on a second piezoelectric crystal wherein the combined movement of the cavity mirror and the output coupler provides a first means for tuning the frequency output of the laser.

23. A laser as claimed in claim 17 wherein the apparatus for scanning the operating frequency of the laser comprises a pair of Brewster plates and a cavity mirror mounted on a piezoelectric crystal wherein the combined movement of the Brewster plates and the cavity mirror provides a second means for tuning the frequency output of the laser.

24. A laser as claimed in claim 18 wherein the anti-reflection coating is optimised for efficient operation with a refractive index of the material and a lasing frequency of the laser.

25. A laser as claimed in claim 17 wherein the first surface of the heatspreader comprise a wedge.

26. A laser as claimed in claim 17 wherein the heatspreader comprises a single diamond crystal.
